(19) United States
(12) Patent Application Publication
(10) Pub. No.: US 2023/0070568 A1
(43) Pub. Date: Mar. 9, 2023

(54) PHOTOELECTRIC CONVERSION DEVICE

(71) Applicant: CANON KABUSHIKI KAISHA, Tokyo (JP)

(72) Inventors: Hideo Kobayashi, Tokyo (JP); So Hasegawa, Kanagawa (JP); Hajime Hayami, Kanagawa (JP)

(21) Appl. No.: 17/900,971

(22) Filed: Sep. 1, 2022

(30) Foreign Application Priority Data
Sep. 8, 2021 (JP) 2021-146424

(51) Int. Cl. H01L 27/146

(52) U.S. Cl. CPC H01L 27/14603; H01L 27/14636; H01L 27/14643

(57) ABSTRACT

A photoelectric conversion device comprising: a pixel signal line configured to transmit a pixel signal; a ramp wire configured to transmit a ramp signal; a comparator configured to compare the pixel signal to the ramp signal; and a capacitive element disposed to have at least a part thereof overlapping the ramp wire in plan view.

### BACKGROUND OF THE INVENTION

### Field of the Invention

The present disclosure relates to a photoelectric conversion device.

### Description of the Related Art

A photoelectric conversion device including a ramp wire and capacitive elements connected to the ramp wire is disclosed is WO 2016/013413. In WO 2016/013413, the capacitive elements are provided in a region between the ramp wire and a column comparator.

While a size reduction is required of a photoelectric conversion device, when capacitive elements are arranged as in WO 2016/013413, a chip area is undesirably increased by a space in which the capacitive elements are arranged.

### SUMMARY OF THE INVENTION

It is therefore an object of the present disclosure to provide a photoelectric conversion device which allows a greater chip area reduction than allowed conventionally.

The first aspect of the disclosure is 1 photoelectric conversion device comprising: a pixel signal line configured to transmit a pixel signal; a ramp wire configured to transmit a ramp signal; a comparator configured to compare the pixel signal to the ramp signal; and a capacitive element disposed to have at least a part thereof overlapping the ramp wire in plan view.

According to the disclosure, there can be provided a photoelectric conversion device which allows a greater chip area reduction than allowed conventionally.

Further features of the present invention will become apparent from the following description of exemplary embodiments with reference to the attached drawings.

### BRIEF DESCRIPTION OF THE DRAWINGS

FIG. 1 is a schematic diagram of a photoelectric conversion device according to a first embodiment;

FIG. 2 is a schematic diagram of the photoelectric conversion device according to the first embodiment;

FIG. 3 is a timing chart of the photoelectric conversion device according to the first embodiment;

FIG. 4 is a schematic diagram of the photoelectric conversion device according to the first embodiment;

FIGS. 5A to 5D are schematic diagrams of the photoelectric conversion device according to the first embodiment;

FIG. 6 is a schematic diagram of a photoelectric conversion device according to a second embodiment;

FIG. 7 is a schematic diagram of the photoelectric conversion device according to the second embodiment;

FIG. 8 is a schematic diagram of the photoelectric conversion device according to the second embodiment;

FIG. 9 is a schematic diagram of the photoelectric conversion device according to the second embodiment;

FIG. 10 is a schematic diagram of a photoelectric conversion device according to a third embodiment;

FIG. 11 is a timing chart of the photoelectric conversion device according to the third embodiment;

FIG. 12 is a timing chart of the photoelectric conversion device according to the third embodiment;

FIG. 13 is a diagram illustrating an example of a configuration of a photoelectric conversion system according to a fourth embodiment; and

FIGS. 14A and 14B are diagrams illustrating an example of respective configurations of a photoelectric conversion system and a moving body each according to the fifth embodiment.

### DESCRIPTION OF THE EMBODIMENTS

Referring to the drawings, a specific description will be given below of embodiments of a photoelectric conversion device according to the present disclosure. Note that the following description is only an example for describing the present disclosure, and the present disclosure is not limited to the following embodiments. The present disclosure can variously be modified within the scope of the technical idea thereof. Note that, in each of the embodiments described below, a description will be given with emphasis on an imaging device as an example of the photoelectric conversion device. However, each of the embodiments is not limited to the imaging device, and is also applicable to another example of the photoelectric conversion device. Examples of another photoelectric conversion device include a distance measurement device (a device for distance measurement using focal detection or TOF (Time of Flight) or the like), a light measurement device (a device for measurement of an amount of incident light or the like), and the like.

### First Embodiment

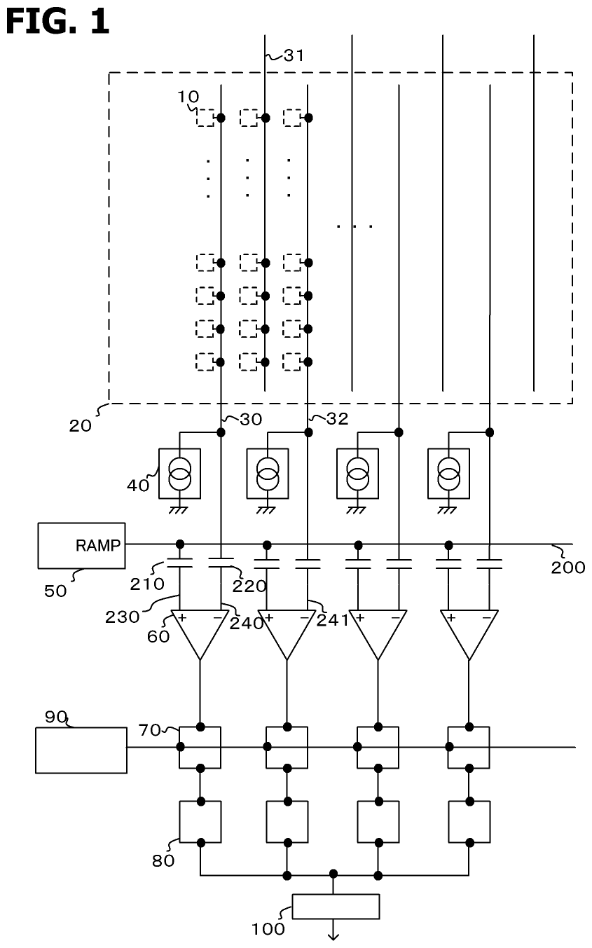

FIG. 1 is a schematic diagram illustrating a configuration of a photoelectric conversion device according to the first embodiment. In FIG. 1, 10 denotes pixels, 20 denotes a pixel array, 30, 31, and 32 denote vertical lines (pixel signal lines), 40 denotes current sources, 50 denotes a ramp signal generation circuit, 60 denotes comparators, 70 denotes first memories, 80 denotes second memories, 90 denotes a counter, and 100 denotes an output circuit. In addition, 200 denotes a ramp wire, 210 denotes ramp input capacitors, 220 denotes pixel input capacitors, 230 denotes a ramp input wire, and 240 denotes a pixel input wire. Thus, to each of the comparators 60, a ramp signal and a pixel signal are capacitively coupled (C-coupled) to be input. Each of the ramp input capacitors 210 has one end connected to the ramp wire 200 and another end connected to the comparator 60. Each of the pixel input capacitors 220 has one end connected to the vertical line 30 and another end connected to the comparator 60.

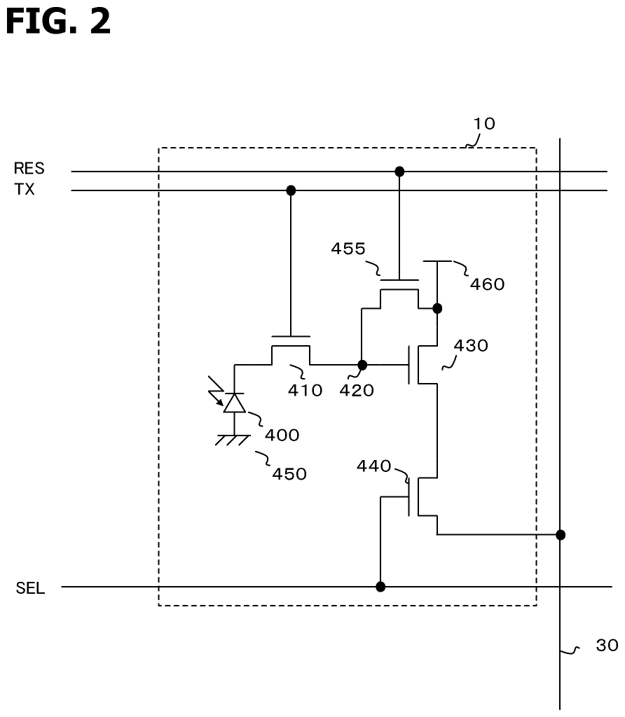

In the pixel array 20, the pixels 10 are arranged in a matrix configuration. FIG. 2 is a diagram illustrating an example of a circuit of each of the pixels 10. In FIG. 2, 400 denotes a photodiode, 410 denotes a transfer transistor, 420 denotes a floating diffusion, 430 denotes a source follower transistor, 440 denotes a selection transistor, and 455 denotes a reset transistor. The reset transistor 455 resets the floating diffusion 420. Photocharge generated in the photodiode 400 is transferred to the floating diffusion 420 through turning ON of the transfer transistor 410 and converted to a signal voltage by a parasitic capacitance accompanying the floating diffusion 420. Then, the signal voltage is output to the vertical line 30 via each of the source follower transistor 430 and the selection transistor 440. The source follower transistor 430 is included together with the current source 40 in FIG. 1 in the source follower, and the signal voltage on the floating diffusion 420 is buffered in the source follower to be output as the pixel signal to the vertical line 30. The pixel signal is transmitted to the comparator 60 via the vertical line 30.

Each of the comparators 60 compares the pixel signal in the vertical line 30 to a ramp signal output from the ramp signal generation circuit 50. More specifically, the comparator 60 compares the pixel signal input thereto from the pixel input wire 240 via each of the vertical line 30 and the pixel input capacitor 220 to the ramp signal input thereto via each of the ramp wire 200 and the ramp input capacitor 210. Each of the first memories 70 retrieves a count signal from the counter 90 at timing of inversion of an output from the comparator 60. As a result, signals from the pixels 10 are subjected to AD conversion. A digital signal from the first memory 70 is transferred to the second memory 80, and then output to the outside of a chip via the output circuit 100.

While the first embodiment has shown an example in which the plurality of circuits use the shared counter 90, a configuration in which counters are provided for respective circuits corresponding to individual vertical lines, and a shared count clock is supplied to each of the counters is also common. To such a configuration also, the present disclosure is applicable. In such a configuration, the number of the counters 90 is not one, and the respective counters 90 are arranged in association with the individual first memories 70. Note that, in FIG. 1, a circuit subsequent to the vertical line 31 connected to the pixels 10 in an odd-numbered column in the pixel array 20 is substantially the same as that connected to the vertical line 30, and therefore the illustration thereof is omitted.

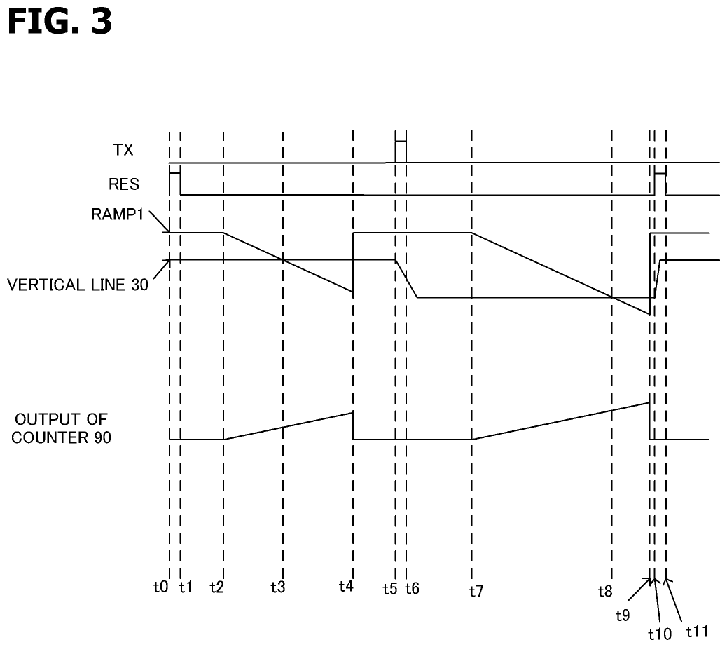

FIG. 3 is a timing chart illustrating an operation of the photoelectric conversion device according to the first embodiment. Referring to FIG. 3, a description will be given below of the operation.

At times t0 to t1, a control signal RES in FIG. 2 is on a HIGH level to turn ON the reset transistor 455 and thereby reset the floating diffusion 420. Accordingly, a potential in the vertical line 30 is on a reset level. At the time t1, the control signal RES is brought to a LOW level to turn OFF the reset transistor 455. Then, at a time t2, a slope operation of the RAMP signal is started. In addition, a counter signal output from the counter 90 continues to be counted up. At a time t3, the RAMP signal to be input to the comparator becomes equal to a signal in the vertical line to invert the output from the comparator. A time period required by the inversion to occur is measured by the counter 90 and held in the first memory 70, thereby effecting AD conversion on the reset level. At a time t4, the RAMP signal is reset.

At times t5 to t6, a control signal TX in FIG. 2 is on the HIGH level to turn ON the transfer transistor 410 and thereby allow the photocharge to be transferred from the photodiode 400 to the floating diffusion 420. A potential at the floating diffusion 420 decreases depending on an amount of the charge. As a result, the potential in the vertical line 30 decreases. At a time t7, the slope operation of the RAMP signal is started again. At a time t8, the output from the comparator is inverted again. By measuring the time period to the inversion by using the counter, an optical signal level is subjected to the AD conversion.

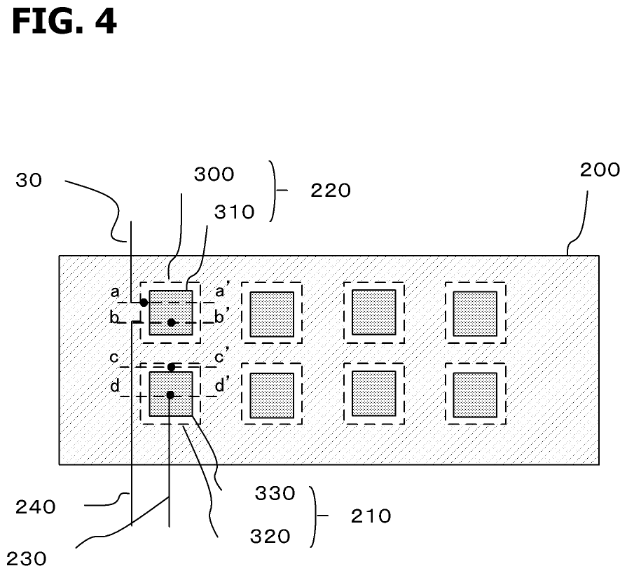

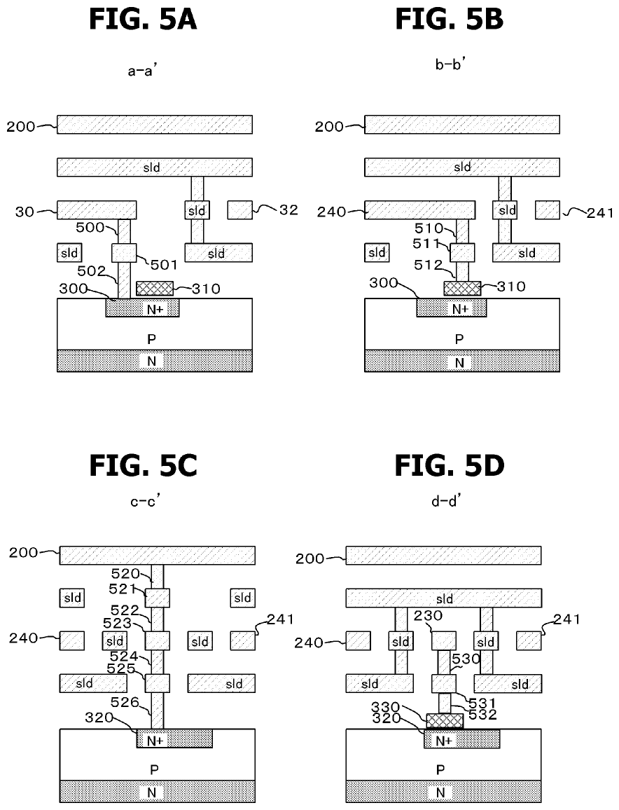

FIG. 4 illustrates a plan view of the ramp wire 200 in the photoelectric conversion device according to the first embodiment. FIGS. 5A to 5D illustrate respective cross-sectional views along broken line portions a-a′, b-b′, c-c′, and d-d′ in FIG. 4.

The ramp input capacitor 210 includes an N⁺ diffusion layer region 320 and a POL (polysilicon) electrode 330. Meanwhile, the pixel input capacitor 220 includes an N⁺ diffusion layer region 300 and a POL electrode 310. In the first embodiment, the ramp input capacitor 210 and the pixel input capacitor 220 are disposed to overlap the ramp wire 200 in plan view. This reduces a chip area of the photoelectric conversion device and can achieve a cost reduction.

Note that, in the first embodiment, both of the ramp input capacitors 210 and the pixel input capacitors 220 are disposed to be included in the ramp wire 200 in plan view, but the present disclosure is not limited thereto. As long as at least a part of either one of the ramp input capacitor 210 and the pixel input capacitor 220 is disposed to overlap the ramp wire 200 in plan view, the effect of reducing the chip area is obtainable. In FIG. 4, each of sizes of the ramp input capacitors 210 and the pixel input capacitors 220 is smaller than a width (a vertical length over a surface of a paper sheet with FIG. 4) of the ramp wire 200, but each of the sizes of the ramp input capacitors 210 and the pixel input capacitors 220 may also be larger than the width of the ramp wire 200.

FIG. 5A is a cross-sectional view along the broken line portion a-a′ in FIG. 4. In this portion, the vertical line 30 is connected to the N⁺ diffusion layer region 300 via each of a via 500, a wire 501, and a via 502. Note that each of wires denoted by sld in the figure is a shield wire for reducing signal-to-signal capacitive coupling between the upper wire 200, the lower wires 30, 32, and 501, and the electrode 310. The shield wire is grounded to, e.g., a GND node to reduce the signal-to-signal capacitive coupling. The shield wires provide shielding, e.g., between the vertical lines 30 and 32 and the ramp wire 200, between the vertical line 32 and the POL electrode 310, and between like components. Consequently, it becomes possible to reduce a signal error due to the capacitive coupling and suppress column-to-column crosstalk.

FIG. 5B is a cross-sectional view along the broken line portion b-b′ in FIG. 4. In this portion, the pixel input wire 240 is connected to the POL electrode 310 via each of a via 510, a wire 511, and a via 512. Note that each of wires denoted by sld in the figure is similarly the shield wire for reducing the signal-to-signal capacitive coupling. The shield wires provide shielding, e.g., between each of the pixel input wire 240 and a pixel input wire 241 and the ramp wire 200, between the pixel input wire 241 and the POL electrode 310, and between like components. Thus, it is possible to suppress the column-to-column crosstalk.

FIG. 5C is a cross-sectional view along a broken line portion c-c′ in FIG. 4. In this portion, the ramp wire 200 is connected to the N⁺ diffusion layer region 320 via each of a via 520, a wire 521, a via 522, a wire 523, a via 524, a wire 525, and a via 526. Note that each of wires denoted by sld in the figure is similarly the shield wire for reducing the signal-to-signal capacitive coupling. The shield wires provide shielding, e.g., between the pixel input wires 240 and 241 and each of the ramp wire 200 and the N⁺ diffusion layer region 320. The shield wires also provide shielding between the pixel input wires 240 and 241 and each of the via 520, the wire 521, the via 522, the wire 523, the via 524, the wire 525, and the via 526. Thus, it is possible to suppress the column-to-column crosstalk.

FIG. 5D is a cross-sectional view along the broken line portion d-d′ in FIG. 4. In this portion, the ramp input wire 230 is connected to the POL electrode 330 via each of a via 530, a wire 531, and a via 532. Note that each of wires denoted by sld in the figure is similarly the shield wire for reducing the signal-to-signal capacitive coupling. The shield wires provide shielding, e.g., between the pixel input wires 240 and 241 and the ramp wire 200, between the pixel input wire 241 and the POL electrode 330, and between like components. Thus, it is possible to suppress the column-to-column crosstalk.

Note that an area (size in plan view) of each of the shield wires may appropriately be set larger than each of electrode areas of the ramp input capacitors 210 and the pixel input capacitors 220. For example, it is assumed that the shield wire has substantially the same shape as that of the ramp wire in which openings are provided in portions to be provided with the vias and the like. By increasing the area of the shield wire, it is possible to more effectively suppress the crosstalk.

Thus, in the first embodiment, the ramp wire 200 is disposed to overlap the ramp input capacitors 210 and the pixel input capacitors 220 each corresponding to a capacitive element in plan view. Thus, it is possible to reduce the chip area and achieve a cost reduction. In addition, the vertical line 30 is disposed between the ramp wire 200 and each of the ramp input capacitor 210 and the pixel input capacitor 220 in a direction perpendicular to a substrate. In addition, the shield wires are used to provide shielding between the vertical line 30 and the ramp wire, between the vertical line 30 and the capacitive elements, and between like components. Such configurations are used to suppress the crosstalk.

Note that forms of the imaging device and the photoelectric conversion device are not limited to those described above. For example, each of the pixels 10 is not limited to that illustrated in FIG. 2. The pixel 10 may also be configured such that a capacitance of the floating diffusion 420 is switchable. The pixel 10 may also have a form in which a plurality of photodiodes share one floating diffusion. The pixel may also be such that a plurality of photodiodes are formed under the same microlens to allow a phase difference to be detected. In a case where there the vertical line 30 includes a plurality of the vertical lines 30 in each one of pixel columns, the pixel may also have a form having a plurality of the selection transistors 440. The comparator 60 may also be configured to have a capacitor and a switch each for an auto-zero operation. The photoelectric conversion device may also be a stacked type or a stacked type having a three layer structure.

### Second Embodiment

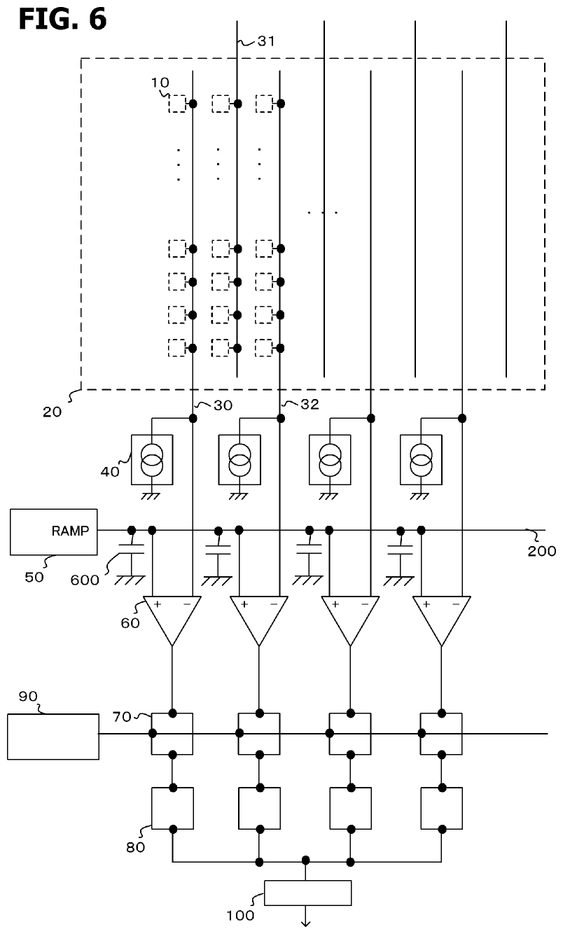

Referring to FIGS. 6 to 8, a description will be given below of a photoelectric conversion device according to the second embodiment. In the second embodiment, the photoelectric conversion device includes capacitive elements intended for a purpose different from that in the first embodiment. A description will be given mainly of a difference from the first embodiment.

FIG. 6 is a schematic diagram illustrating a configuration of the photoelectric conversion device according to the second embodiment. Compared to the photoelectric conversion device in the first embodiment, not the ramp input capacitors 210 and the pixel input capacitors 220, but earth capacitors 600 are connected to the ramp wire 200. When the output from each of the comparators 60 is inverted, the comparator 60 causes a potential variation resulting from kickback to the ramp wire 200. By adding the earth capacitors 600, it is possible to reduce a ramp signal voltage variation. Additionally, by limiting a bandwidth for the ramp signal generation circuit 50 (RF rejection), it is possible to reduce noise superimposed on the ramp signal.

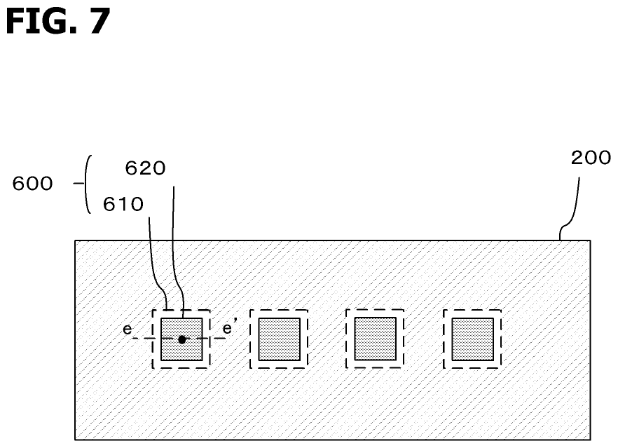

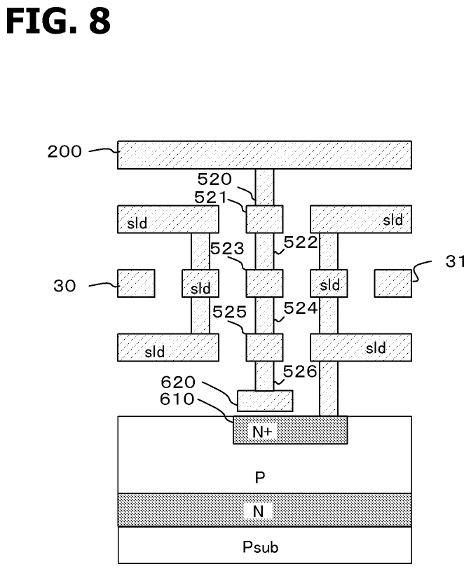

FIG. 7 illustrates a plan view of the ramp wire 200 in the photoelectric conversion device according to the second embodiment. FIG. 8 illustrates a cross-sectional view along a broken line portion e-e′ in FIG. 7.

Each of the earth capacitors 600 includes an N⁺ diffusion layer region 610 and a POL electrode 620. As illustrated in the drawing, in the second embodiment, the ramp wire 200 and the earth capacitors 600 are disposed to overlap each other in plan view. This reduces a chip area and can achieve a cost reduction. It is sufficient for at least a part of each of the earth capacitors 600 to overlap the ramp wire 200 in plan view, and the earth capacitors 600 need not necessarily be included completely in the ramp wire 200 as in FIG. 7.

FIG. 8 is a cross-sectional view along the broken line portion e-e′ in FIG. 7. In this portion, the ramp wire 200 is connected to the POL electrode 620 via each of the via 520, the wire 521, the via 522, the wire 523, the via 524, the wire 525, and the via 526. Note that each of wires denoted by sld in the figure is the shield wire for reducing the signal-to-signal capacitive coupling. The shield wires provide shielding, e.g., between the vertical lines 30 and 31 and each of the ramp wire 200 and the POL electrode 620. The shield wires also provide shielding between the vertical lines 30 and 31 and each of the via 520, the wire 521, the via 522, the wire 523, the via 524, the wire 525, and the via 526. Thus, it is possible to suppress the column-to-column crosstalk. For the earth capacitor, it is sufficient to thus shield only the via portions from the ramp wire 200 to the POL electrode 620, and therefore the second embodiment can more easily be implemented than the first embodiment, while suppressing the crosstalk.

Note that, as illustrated in FIG. 6, each of the earth capacitors 600 has one end connected to the ramp wire 200 and another end connected to GND. It is sufficient for the other end of the earth capacitor 600 to be connected to a constant voltage node, and therefore the earth capacitor 600 may also be connected to VDD (a power source), not to GND. However, to avoid superimposition of power source noise on the ramp wire 200, the earth capacitor 600 is more preferably connected to GND than to VDD. Still more preferably, the earth capacitor 600 is connected to GND different from the same GND as connected to a P substrate provided with pixels in terms of avoiding noise superimposition on the ramp wire 200.

To reduce effects of the potential variation resulting from the kickback anywhere, the earth capacitors 600 are distributed to be arranged at a plurality of locations, as illustrated in FIGS. 6 and 7. Note that, in FIG. 6, the earth capacitors 600 are provided for all the columns, but it may also be possible to provide the one earth capacitor 600 for the plurality of columns or provide the plurality of earth capacitors 600 for each one of the columns.

To reduce crosstalk, as illustrated in FIG. 8, the capacitive elements 600 are preferably arranged at locations other than those immediately below the vertical lines 30 and 31. In other words, the earth capacitors 600 are preferably arranged not to overlap the vertical lines 30 and 31 in plan view.

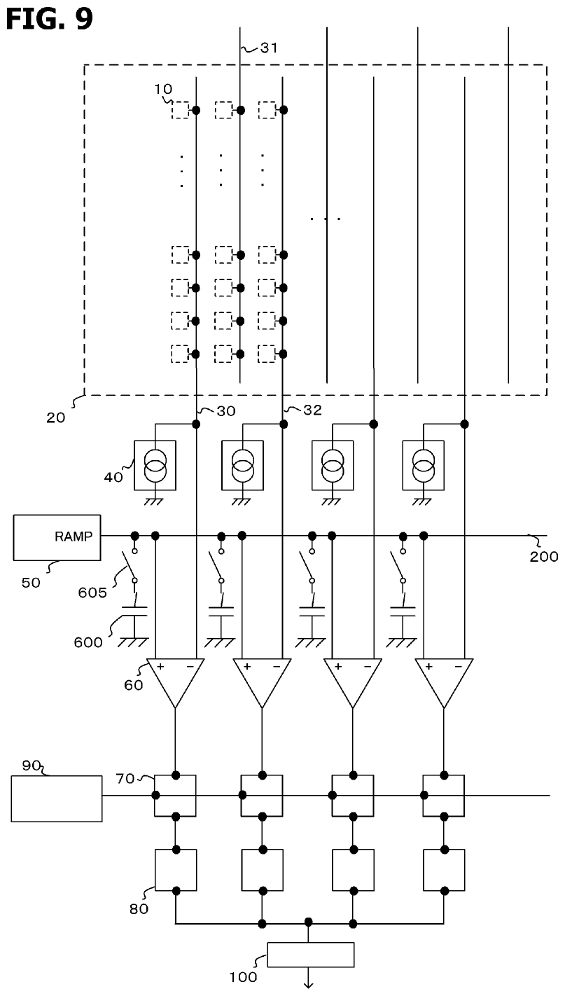

Alternatively, as illustrated in FIG. 9, each of the capacitive elements 600 may also be connected to the ramp wire 200 via a switch 605. This allows selective use of the capacitive elements 600 depending on an operation mode such that, in a mode in which, e.g., a response time for resetting a potential in the ramp wire 200 is more important than a noise reduction, the switch 605 is brought into the OFF state. By additionally disposing the switch 605 also below the ramp wire 200, it is possible to suppress effects on area.

### Third Embodiment

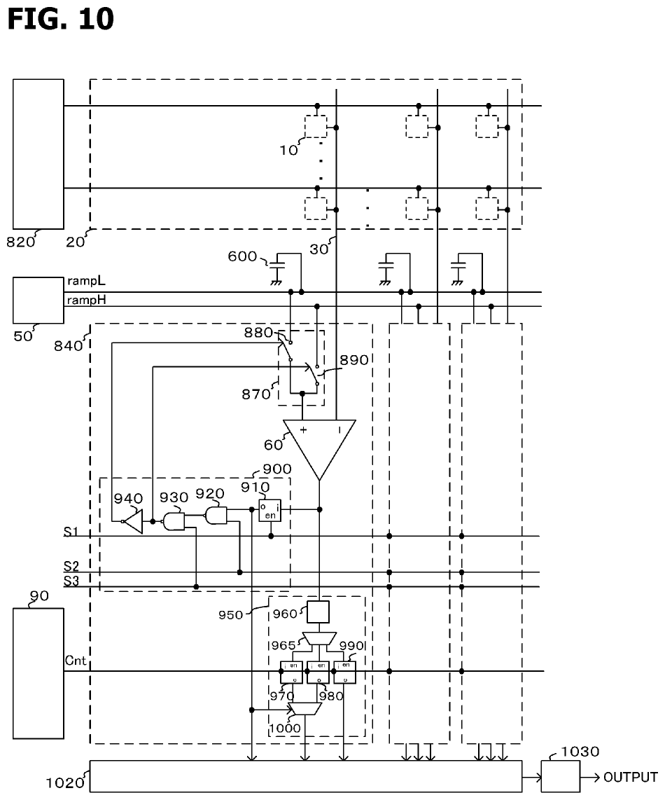

Referring to FIGS. 10 to 12, a description will be given of a photoelectric conversion device according to the third embodiment. A description will be given mainly of a difference from the second embodiment (FIG. 6).

FIG. 10 is a schematic diagram illustrating a configuration of the photoelectric conversion device according to the third embodiment. In the third embodiment, two ramp signals rampL and rampH with different inclinations are used. In FIG. 10, 820 denotes a vertical scanning circuit, while 840 denotes a column AD converter. The column AD converter 840 includes a switching portion 870, a selection portion 900, and a memory portion 950. The switching portion 870 includes switches 880 and 890. The selection portion 900 includes a latch 910, NAND gates 920 and 930, and an INV gate 940. The memory portion 950 includes a pulse generator 960, a selector 965, latches 970, 980, and 990, and a selector 1000. In addition, 1020 denotes a horizontal scanning circuit, while 1030 denotes an output circuit. From the ramp signal generation circuit 50, the two ramp signals rampL and rampH with the different inclinations are output. To the selection portion 900, control signals s1, s2, and s3 are supplied.

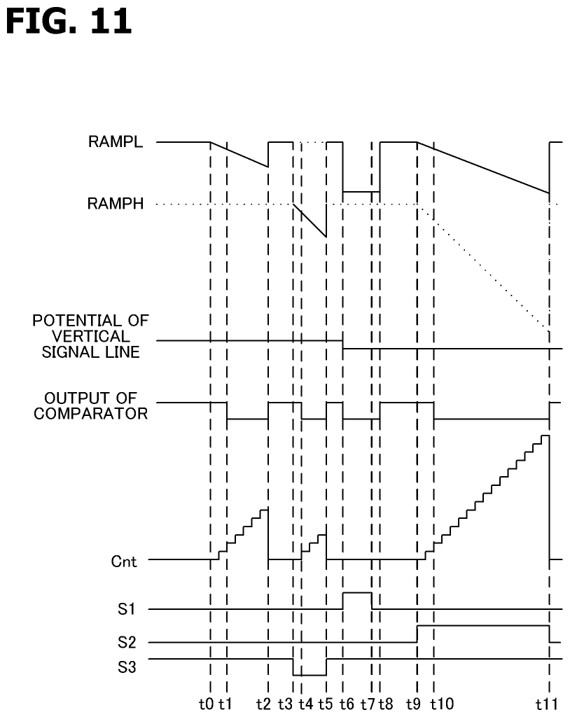

Referring to FIG. 11, a description will be given of an operation of the column that performs AD conversion on the signals output from the pixels 10 to the vertical signal line 30 when an illuminance is low.

At a time t0, the control signal s2 is on a L level, while the control signal s3 is on a H level. As a result, in the switching portion 870, the switch 880 is brought into an ON state, while the switch 890 is brought into an OFF state, to result in a state where the ramp signal rampL is input to a non-inverting input terminal of the comparator 60. Meanwhile, the potential in the vertical signal line 30 is on a level equivalent to the reset level of the pixel 10. At this time, a voltage at the non-inverting input terminal is higher than a voltage at an inverting input terminal, and an output from the comparator is on the H level.

After the time t0, a potential of the ramp signal rampL continues to decrease, while a count signal cnt continues to be counted up. When the ramp signal rampL becomes lower than the potential in the vertical signal line 30, the output from the comparator 60 shifts from the H level to the L level, the pulse generator 960 generates a short-period one-shot pulse, and the selector 965 supplies the pulse to the latch 970. By such an operation, at a time t1, the count signal cnt is written to the latch 970. This serves as a result of the AD conversion performed on the reset level by using the ramp signal rampL.

At a time t2, the ramp signal rampL and the count signal cnt are reset, and the output from the comparator 60 returns from the L level to the H level. Then, at a time t3, the control signal s3 shifts to the L level. As a result, in the switching portion 870, the switch 880 is turned OFF, while the switch 890 is turned ON. This results in a state where the ramp signal rampH is input to the non-inverting input terminal of the comparator 60.

After the time t3, a potential of the ramp signal rampH continues to decrease, while the count signal cnt continues to be counted up. As a result of shifting of the output from the comparator 60 again to the L level, the pulse generator 960 generates the one-shot pulse, and the selector 965 supplies the pulse to the latch 980. By such an operation, at a time t4, the count signal cnt is written to the latch 980. This serves as a result of the AD conversion performed on the reset level by using the ramp signal rampH.

At a time t5, the ramp signal rampH and the count signal cnt are reset, and the output from the comparator 60 returns from the L level to the H level. In addition, the control signal s3 returns to the H level to result in a state where the ramp signal rampL is input again to the non-inverting input of the comparator 60.

At a time t6, the potential in the vertical signal line 30 is on a level equivalent to that of an optical signal. In addition, the potential of the ramp signal rampL is lowered, and the level in the vertical signal line 30 is determined. FIG. 11 illustrates a case where the illuminance is low, and consequently the potential in the vertical signal line 30 becomes higher than that of the ramp signal rampL, and the output from the comparator 60 shifts to the L level. At this time, by bringing the control signal s1 to the H level at times t6 to t7, the L level serving as a result of the determination is written to the latch 910.

At a time t8, by returning the potential of the ramp signal rampL, the output from the comparator 60 returns to the H level. Then, at a time t9, the control signal s2 is brought to the H level to cause the determination result written to the latch 910 to be reflected in the switching portion 870. Since the L level is currently written to the memory 910, in the switching portion 870, the switch 880 is brought into the ON state, while the switch 890 is brought into the OFF state, to result in a state where the ramp signal rampL is input to the non-inverting input terminal of the comparator 60.

After the time t9, the potential of the ramp signal rampL continues to decrease, while the count signal cnt continues to be counted up. At a time t10, the comparator output shifts to the L level to allow a result of the AD conversion performed on the signal level by using the ramp signal rampL to be written to the latch 990. At a time t11, the ramp signal rampL and the count signal cnt are reset. In a case in FIG. 11, on the basis of the determination result written to the latch 910, the selector 1000 selectively outputs the AD conversion result written to the latch 970.

After the time t11, the determination result and the AD conversion results which are written to the latches 910, 970 and 990 are horizontally transferred via the horizontal scanning circuit 1020. The output circuit 1030 performs processing such as S-N processing on the basis of the AD conversion results from the latches 970 and 990, and then outputs a signal. At this time, depending on the determination result from the latch 910, different processing is additionally performed. A description will be given later of this point.

Thus, when the signal level in the vertical signal line 30 is equivalent to that at a low illuminance, the ramp signal rampL with the smaller inclination is selectively used to thus reduce random noise resulting from a quantization error or the like and allow high-accuracy AD conversion to be performed.

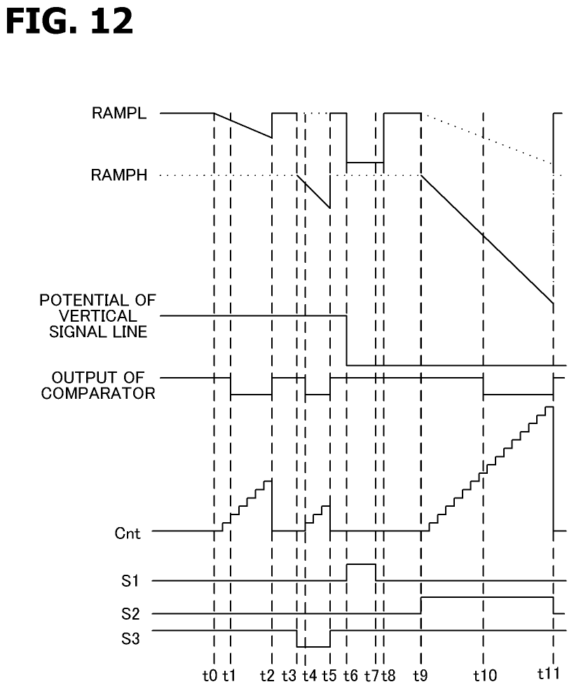

Next, referring to FIG. 12, a description will be given of an operation of the column that performs AD conversion on signals output from the pixels 10 to the vertical signal line 30 when the illuminance is high.

The operation is the same as in FIG. 11 until a time t6. In FIG. 12, a potential reduction in the vertical signal line 30 at the time t6 is large, and consequently the output from the comparator 60 remains on the H level, and the H level is written to the latch 910. In other words, depending on the signal level in the vertical signal line 30, the result written to the latch 910 varies. As a result, after a time t9, to the non-inverting input terminal of the comparator 60, the ramp signal rampH is input.

At a time t10, a result of the AD conversion performed on the signal level by using the ramp signal rampH is written to the latch 990. In the case in FIG. 12, on the basis of the determination result written to the latch 910, the selector 1000 selectively outputs the AD conversion result written to the latch 980.

After a time t11, the determination result and the AD conversion results which are written to the latches 910, 980, and 990 are horizontally transferred via the horizontal scanning circuit 1020. At this time, depending on the determination result in the memory 910, the output circuit 1030 performs processing such as application of a digital gain according to an inclination ratio between the ramp signals rampL and rampH in addition to the S-N processing, and then outputs the signal. It may also be possible to perform correction of an offset difference resulting from different timings of starting the slope operation, different propagation delays, and the like of the ramp signals rampL and rampH, though details thereof are omitted.

As described above, when the signal level in the vertical signal line 30 is equivalent to that at the high luminance, the ramp signal rampH with the larger inclination is selectively used. This increases the random noise in the AD converter 840 due to a quantization error or the like, but optical shot noise appearing on a vertical signal line 30 side is small. Therefore, it is possible to reduce a read time, while minimizing effects on total random noise.

Additionally, in FIG. 10, each of the capacitive elements 600 is added to a signal line for the ramp signal rampL. In the third embodiment also, in the same manner as in the second embodiment (FIGS. 7 and 8), the capacitive element 600 is disposed to overlap the ramp wire 200. By using the capacitive element 600, it is possible to improve an image quality, while giving consideration to a cost reduction. A description will be given below of the image quality improvement achieved by using the capacitive element 600.

The random noise included in the ramp signals rampL and rampH is input to the comparator 60 to vary, e.g., the times t1 and t4 in FIGS. 11 and 12 and thereby appear in output results. The noise simultaneously appears in all the columns, and is therefore row-by-row noise. What results is random lateral stripe noise. Noticeability of the lateral stripe noise in an image is affected by pixel-by-pixel random noise. In other words, when the pixel-by-pixel random noise is large, the row-by-row lateral stripe noise is less noticeable. In still other words, when the pixel-by-pixel random noise is large, the lateral stripe noise resulting from the random noise in the ramp signals is visually less recognizable. In FIG. 10, the ramp signal rampH is used for the AD conversion in the high-luminance column having the large pixel-by-pixel random noise due to optical shot noise. Accordingly, the horizontal stripe noise due to the random noise included in the ramp signal rampH is visually less recognizable. In FIG. 10, the capacitive element 600 is added to the signal line for the ramp signal rampL to be used when a signal having a small amount of the optical shot noise and a small amount of the pixel-by-pixel random noise is to be converted. This can reduce the random noise in the ramp signal rampL and reduce the horizontal stripe noise, while giving consideration to a chip area reduction, i.e., a cost reduction.

As described above, by providing the signal line for the ramp signal rampL with the earth capacitors 600 and thus setting a capacitance value in the signal line for the ramp signal rampL larger than a capacitance value in a signal line for the ramp signal rampH, it is possible to improve the image quality, while giving consideration to a cost reduction. In the same manner as in FIGS. 6 and 7, by arranging the earth capacitors 600 in overlapping relation on the ramp wire 200, it is possible to suppress effects on an area.

### Fourth Embodiment

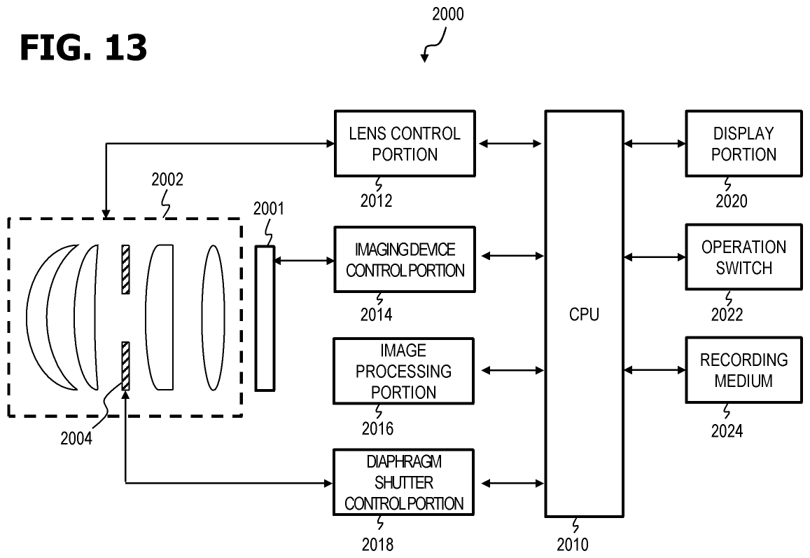

An imaging system according to a fourth embodiment of the present invention will be explained with reference to FIG. 13. FIG. 13 is a block diagram of a schematic configuration of a photoelectric conversion system according to this embodiment.

The photoelectric conversion devices (CMOS image sensor) described in the above first to third embodiments may apply to various photoelectric conversion systems. Applicable photoelectric conversion systems may include, but are not limited to, various types of equipment such as a digital still camera, a digital camcorder, a monitor camera, a copying machine, a facsimile, a mobile phone, an in-vehicle camera, an observation satellite, a medical camera, or the like. The photoelectric conversion systems may also include a camera module including an optical system such as a lens and a photoelectric conversion device (imaging device). FIG. 13 is a block diagram of a digital still camera as an example of those photoelectric conversion systems.

FIG. 13 shows a photoelectric conversion system 2000, which includes a photoelectric conversion device 2001, an imaging optical system 2002, a CPU 2010, a lens control portion 2012, an imaging device control portion 2014, an image processing portion 2016, and a diaphragm shutter control portion 2018. The photoelectric conversion system 2000 also includes a display portion 2020, an operation switch 2022, and a recording medium 2024.

The imaging optical system 2002 is an optical system for forming an optical image of the subject, and includes a lens group, a diaphragm 2004, or the like. The diaphragm 2004 has a function of adjusting light intensity during photography by adjusting its opening size. The diaphragm 2004 also functions as an exposure time adjustment shutter during still image photography. The lens group and the diaphragm 2004 are held movable forward and backward in the optical axis direction. These linked operations may provide a scaling function (zoom function) and a focus adjustment function. The imaging optical system 2002 may be integrated into the photoelectric conversion system or may be an imaging lens mountable to the photoelectric conversion system.

The photoelectric conversion device 2001 is disposed such that its imaging plane is positioned in the image space of the imaging optical system 2002. The photoelectric conversion device 2001 is one of the solid-state photoelectric conversion devices (imaging devices) explained in the first to third embodiments. The photoelectric conversion device 2001 includes a CMOS sensor (pixel portion) and its peripheral circuits (peripheral circuit area). The photoelectric conversion device 2001 includes a plurality of pixels arranged in two dimensions, each pixel including a photoelectric conversion portion. These pixels are provided with color filters to form a two-dimensional single-plate color sensor. The photoelectric conversion device 2001 may photoelectrically convert a subject image imaged by the imaging optical system 2002 for output as an image signal and/or a focus detection signal.

The lens control portion 2012 is to control the forward and backward driving of the lens group in the imaging optical system 2002 to perform scaling operation and focus adjustment. The lens control portion 2012 includes a circuit and/or processing unit configured to achieve those functions. The diaphragm shutter control portion 2018 is to change the opening size of the diaphragm 2004 (for a variable diaphragm value) to adjust light intensity during photography, and is constituted of a circuit and/or processing unit configured to achieve those functions.

The CPU 2010 is a control unit in a camera responsible for various controls of the camera bod, and includes an operation portion, a ROM, a RAM, an A/D converter, a D/A converter, a communication interface circuit, or the like. The CPU 2010 controls the operation of each portion in the camera according to a computer program stored in a ROM or the like. The CPU 2010 performs a series of photography operations such as AF, imaging, image processing, and recording, including detection of the focus state (focus detection) of the imaging optical system 2002. The CPU 2010 also serves as a signal processing portion.

The imaging device control portion 2014 is to control the operation of the photoelectric conversion device 2001 and to A/D convert a signal output from the photoelectric conversion device 2001 and transmit the result to the CPU 2010, and includes a circuit and/or control unit configured to achieve those functions. The photoelectric conversion device 2001 may have the A/D conversion function. The image processing portion 2016 is a processing unit that subjects the A/D converted signal to processing such as y conversion and color interpolation to generate an image signal. The image processing portion 2016 includes a circuit and/or control unit configured to achieve those functions. The display portion 2020 is a display device such as a liquid crystal display device (LCD), and displays information related to a photography mode of the camera, a preview image before photography, a check image after photography, the focused state at the focus detection, or the like. The operation switch 2022 includes a power supply switch, a release (photography trigger) switch, a zoom operation switch, a photography mode selection switch, or the like. The recording medium 2024 is to record a photographed image or the like, and may be built in the photoelectric conversion system or removable such as a memory card.

In this way, the photoelectric conversion system 2000 applied with the photoelectric conversion device 2001 according to the first to third embodiments may provide a high performance photoelectric conversion system.

### Fifth Embodiment

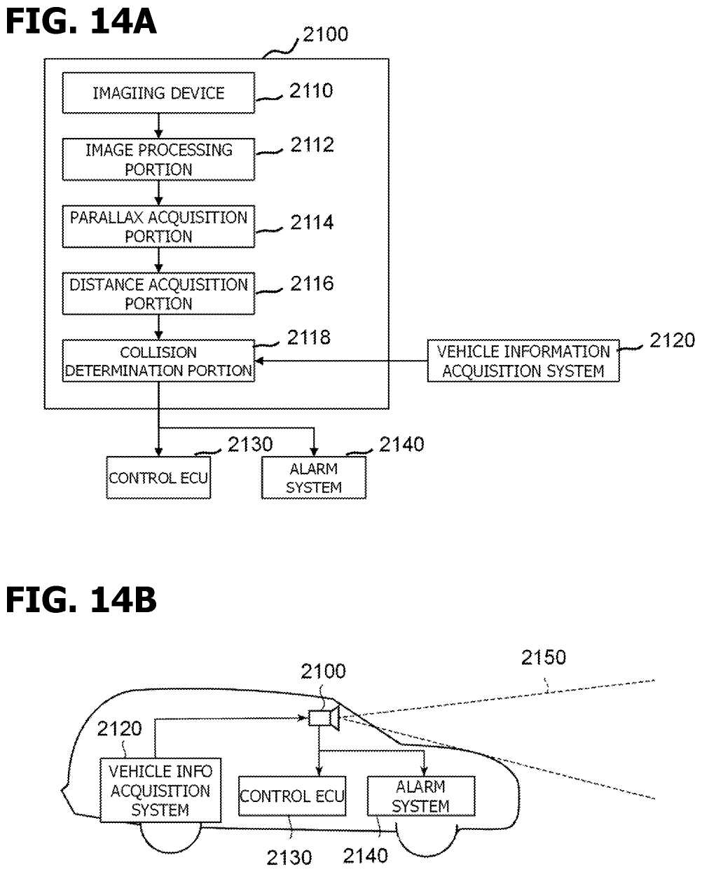

An photoelectric conversion system and a mobile object according to a fifth embodiment of the present invention will be explained with reference to FIGS. 14A and 14B. FIGS. 14A and 14B show configurations of the photoelectric conversion system and mobile object according to this embodiment.

FIG. 14A shows an example of an photoelectric conversion system 2100 associated with an in-vehicle camera. The photoelectric conversion system 2100 has a photoelectric conversion device 2110. The photoelectric conversion device 2110 is any one of the solid-state photoelectric conversion devices (imaging devices) according to the above first to third embodiments. The photoelectric conversion system 2100 has an image processing portion 2112 and a parallax acquisition portion 2114. The image processing portion 2112 is a processing unit that subjects a plurality of sets of image data acquired by the photoelectric conversion device 2110 to image processing. The parallax acquisition portion 2114 is a processing unit that calculates parallax (a phase difference of a parallax image) from the sets of image data acquired by the photoelectric conversion device 2110. The photoelectric conversion system 2100 also includes a distance acquisition portion 2116, which is a processing unit that calculates the distance to the subject based on the calculated parallax. The photoelectric conversion system 2100 also includes a collision determination portion 2118, which is a processing unit that determines a possibility of collision based on the calculated distance. Here, the parallax acquisition portion 2114 and the distance acquisition portion 2116 are examples of information acquiring means that acquires information such as distance information to the subject. In other words, the distance information is information related to parallax, defocus amount, the distance to the subject, or the like. The collision determination portion 2118 may determine a possibility of collision using any of the distance information. The above processing unit may be provided by specially designed hardware or may be provided by general hardware that performs operation based on a software module. In addition, the processing unit may be provided by a Field Programmable Gate Array (FPGA), an Application Specific Integrated Circuit (ASIC), or the like or may be provided by a combination thereof.

The photoelectric conversion system 2100 is connected to a vehicle information acquisition system 2120, and may thus acquire vehicle information including a vehicle speed, a yaw rate, and a rudder angle. The photoelectric conversion system 2100 also has a control ECU 2130 connected thereto. The ECU 2130 is a control unit that outputs a control signal for generating a braking force to the vehicle based on the determination by the collision determination portion 2118. In other words, the control ECU 2130 is an example of a mobile object control means that controls a mobile object based on the distance information. The photoelectric conversion system 2100 is also connected to an alarm system 2140. The alarm system 2140 gives an alarm to the driver based on the determination by the collision determination portion 2118. For example, if the collision determination portion 2118 determines a high possibility of collision, the control ECU 2130 performs a vehicle control that avoids collision and reduces damage by braking, releasing the accelerator, limiting the engine output, or the like. The alarm system 2140 warns the user by sounding an alarm such as sound, displaying alarm information on a screen of a car navigation system or the like, giving vibration to a seatbelt and steering, or the like.

In this embodiment, the surroundings of the vehicle such as front or rear are imaged by the photoelectric conversion system 2100. FIG. 14B shows the photoelectric conversion system 2100 when imaging the front of the vehicle (imaging range 2150). The vehicle information acquisition system 2120 directs the photoelectric conversion system 2100 to operate and perform imaging. Using the photoelectric conversion devices according to the above first to third embodiments as the imaging device 2110, the imaging system 2100 in this embodiment may provide more improved ranging accuracy.

Although the above description shows an example control that prevents collision with other vehicles, the present invention may also apply to a control of autonomous driving following other vehicles, a control of autonomous driving preventing running over a traffic lane, or the like. In addition to a vehicle such as a car, the photoelectric conversion system may also apply to, for example, a mobile object (transportation equipment) such as a vessel, an aircraft, or an industrial robot. The moving device in the mobile object (transportation equipment) is one of various types of drive sources, including an engine, a motor, a wheel, and a propeller. In addition to a mobile object, the photoelectric conversion system may also apply to equipment, such as Intelligent Transport Systems (ITS), that commonly uses the object recognition.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2021-146424, filed on Sep. 8, 2021, which is hereby incorporated by reference herein in its entirety.

What is claimed is:

1. A photoelectric conversion device comprising:
a pixel signal line configured to transmit a pixel signal;
a ramp wire configured to transmit a ramp signal;
a comparator configured to compare the pixel signal to the ramp signal; and
a capacitive element disposed to have at least a part thereof overlapping the ramp wire in plan view.

2. The photoelectric conversion device according to claim 1,
wherein the capacitive element has one end connected to the ramp wire.

3. The photoelectric conversion device according to claim 2,
wherein the capacitive element has another end connected to a constant voltage node.

4. The photoelectric conversion device according to claim 3,
wherein the constant voltage node is a power source or ground.

5. The photoelectric conversion device according to claim 2,
wherein the capacitive element is connected to the ramp wire via a switch.

6. The photoelectric conversion device according to claim 1,
wherein the pixel signal line is provided between the ramp wire and the capacitive element in a direction perpendicular to a substrate.

7. The photoelectric conversion device according to claim 6, further comprising:
a shield wire between the pixel signal line and the ramp wire or between the pixel signal line and the capacitive element.

8. The photoelectric conversion device according to claim 7,
wherein an area of the shield wire is larger than an electrode area of the capacitive element.

9. The photoelectric conversion device according to claim 1,
wherein the capacitive element includes a plurality of the capacitive elements distributed to be arranged at a plurality of locations.

10. The photoelectric conversion device according to claim 1, further comprising:
a second ramp wire configured to transmit a second ramp signal with an inclination larger than that of the ramp signal.

11. The photoelectric conversion device according to claim 10,
wherein the capacitive element connected to the ramp wire has a capacitance larger than that of a capacitive element connected to the second ramp wire.

12. A photoelectric conversion system comprising:
the photoelectric conversion device according to claim 1; and
a signal processing unit that processes a signal output from the photoelectric conversion device.

13. A moving body comprising:
the photoelectric conversion device according to claim 1,
a moving device;
a processing device configured to acquire information from a signal output from the photoelectric conversion device; and
a control device configured to control the moving device on the basis of the information.
